(19) United States
(12) Patent Application Publication
(10) Pub. No.: US 2024/0392444 A1
(43) Pub. Date: Nov. 28, 2024

(54) COATING COMPOSITIONS, METHODS TO PRODUCE NON-STICK SURFACES AND NON-STICK SURFACES MADE THEREFROM

(71) Applicant: IBC Materials & Technologies, LLC, Lebanon, IN (US)

(72) Inventors: Roman Motyka, Zionsville, IN (US); Solomon Berman, Carmel, IN (US)

(21) Appl. No.: 18/665,696

(22) Filed: May 16, 2024

Related U.S. Application Data
(60) Provisional application No. 63/503,592, filed on May 22, 2023.

(51) Int. Cl. C23C 28/04

(52) U.S. Cl. CPC C23C 28/046

(57) ABSTRACT

A coating on a surface of a metallic substrate which includes one or more layers of DLC (Diamond-Like Carbon) containing silicon and oxygen. The coatings optionally have an intermediate layer, such as a nitrocarburized layer. A method of producing a non-stick coating on a surface of a metallic material. The method includes producing one of nitriding layer, nitrocarburization layer, and carburization layer on the surface of a metallic material by one of ion plasma nitriding, gas nitriding, and salt bath nitriding; and producing one or more layers of DLC, each layer containing silicon and oxygen on top of and in contact with the nitrocarburized layer by a plasma enhanced chemical vapor deposition (PECVD) vacuum process. An article containing on its surface one or more layers of DLC containing silicon and oxygen, and optionally an intermediate layer.

### CROSS-REFERENCE TO RELATED APPLICATIONS

The present non-provisional application is related to and claims the priority benefit of U.S. Provisional Patent Application Ser. No. 63/503,592, filed May 22, 2023, the contents of which are hereby incorporated by reference in their entirety into the present disclosure.

### TECHNICAL FIELD

The present disclosure generally relates to coatings on articles of manufacture to produce non-stick surfaces.

### BACKGROUND

This section introduces aspects that may help facilitate a better understanding of the disclosure. Accordingly, these statements are to be read in this light and are not to be understood as admissions about what is or is not prior art.

There are many applications where a non-stick surface is highly desired. A non-stick surface is generally understood to be a surface that allows food to cook while preventing food particles from sticking to it. An example is non-stick cookware commonly available where the surface on which food is cooked has such a property that the food does not stick to the surface during cooking.

While this disclosure may refer to non-stick surfaces in the context of cooking, it is to be understood that the compositions and methods of this disclosure are applicable to non-cooking applications where similar non-stick surfaces are desired. Another desirable attribute of such non-stick surfaces is the quality of being scratch resistant.

To enhance the functionality of metal cookware, various coatings have been developed to make them non-stick, scratch-resistant, and/or easy to clean. PTFE (Polytetrafluoroethylene), a fluoropolymer known for its excellent non-stick properties, was one of the first coatings used for this purpose. However, PTFE has several shortcomings. Firstly, it is very soft and can easily scratch or peel off, exposing the underlying metal. Secondly, temperature exposure to above about 250° C. causes it to degrade, leading to the release of harmful chemicals and decreased non-stick performance.

Other coatings, such as ceramics and enamels, have been developed as alternatives to PTFE. These coatings generally have superior durability and scratch-resistance, but inferior non-stick properties. They can also chip and crack easily due to their brittle nature. Depending on their composition, some sol-gel ceramic coatings have similar temperature limits to PTFE, above which they will degrade or decompose.

Most coatings available today are thick >30 micrometers, which increases cost and can cause issues with finer tolerances, edges, or complex shapes. High thickness can also decrease thermal performance of cooking surfaces due to the thermal barrier properties of most ceramic, polymer, or composite materials. Thermal gradients and temperature shock exposure can lead to cracking or delamination of the coatings.

Some coatings, such as those applied by thermal spray processes, are deposited in a rough surface condition, and must go through costly grinding/polishing procedures to achieve a smoother finish suitable for non-stick applications.

Stainless steels are often used in cookware applications for their excellent corrosion resistance. However, they are relatively soft and highly susceptible to sticking during cooking. Durable alternatives to PTFE are typically hard, which creates a significant mismatch in mechanical properties at the interface between the coating and the steel substrate. Hence, the adhesion and load bearing strength suffer, and this contributes to cracking and chipping susceptibility.

Corrosion resistance is extremely important for long-term durability of cookware coatings. While PTFE is considered very chemically inert, most stainless steels and ceramics are susceptible to certain acidic or caustic conditions, especially in combination with heat. Since cooking and washing can expose coatings to a wide range of temperatures and pH conditions, existing PTFE-alternatives often degrade in non-stick performance over time due to corrosion or other chemical interactions at the surface.

Some attempts have been made to develop durable composites combining hard materials, such as metal oxides, with soft non-stick materials, such as PTFE. While these composites can yield improved durability, they are still susceptible to the weaknesses of one or more sub-components, such as temperature limitations, corrosion, or long-term degradation. There are typically moderate-to-severe trade-offs in the non-stick performance of these composite materials compared to pure PTFE.

Hence there is an unmet need for no-stick coatings that are thinner, scratch resistant and corrosion resistant relative to the coatings in use for the non-stick coating applications.

### SUMMARY

A coating on a surface of a metallic substrate is disclosed. The coating includes one or more layers of DLC (Diamond-Like Carbon), each layer of DLC containing silicon and oxygen. The coatings can optionally use an intermediate layer, such as, but not limited to a nitrocarburized layer.

A method of producing a non-stick coating on a surface of a metallic material is disclosed. The method includes producing one of nitriding layer, nitrocarburization layer, and carburization layer on the surface of a metallic material by one of ion plasma nitriding, gas nitriding, and salt bath nitriding; and producing one or more layers of DLC, each DLC layer containing silicon and oxygen on top of and in contact with the nitrocarburized layer by a plasma enhanced chemical vapor deposition (PECVD) vacuum process.

An article containing on a surface of the article one or more layers of DLC each layer of DLC containing silicon and oxygen is disclosed. An article comprising a surface containing a nitrocarburized layer; and one or more layers of DLC each DLC layer containing silicon and oxygen on top of and in contact with the nitrocarburized layer is disclosed.

### BRIEF DESCRIPTION OF DRAWINGS

While some of the figures shown herein may have been generated from scaled drawings or from image that are scalable, it is understood that such relative scaling within a figure are by way of example, and are not to be construed as limiting.

FIG. 1 shows a schematic representation of the cross section of an article comprising the coatings of this disclosure.

FIG. 2 shows ASTM C1624 scratch adhesion testing using a Rockwell C diamond-tipped indenter and a progressive load of 1-51 N across 5 mm of length. Top: stainless steel coated with PTFE. Bottom: stainless steel coated with the coating of this disclosure.

FIG. 3 shows ASTM G48 ferric chloride crevice corrosion test results. Left: bare stainless steel after 20 hrs., with heavy pitting. Right: DLC coated stainless steel after 48 hrs, with no corrosion.

FIG. 4 shows that a water contact angle of 99° has been obtained on the surface of the coating of this disclosure, tested in accordance with ISO 19403-2.

FIG. 5 shows an image of an “oil-free egg test” performed on the coating of this disclosure. The cooked egg lifts freely off the cooking surface with no sticking or residues.

### DETAILED DESCRIPTION

For the purposes of promoting an understanding of the principles of the disclosure, reference will now be made to the embodiments illustrated in the drawings and specific language will be used to describe the same. It will nevertheless be understood that no limitation of the scope of the disclosure is thereby intended, such alterations and further modifications in the illustrated device, and such further applications of the principles of the disclosure as illustrated therein being contemplated as would normally occur to one skilled in the art to which the disclosure relates.

The present disclosure describes a diamond-like carbon (DLC) coating with a novel combination of durability, corrosion resistance, and non-stick properties, applied to metallic cookware surfaces, such as pots, pans, racks, sheets, utensils, tools, and cutting boards. The coating is preferably applied to a stainless-steel material which is diffusion nitrocarburized at low temperature prior to coating, in a duplex process, as known in the industry. However, suitable substrates for purposes of effecting this coating on a surface, other than stainless steel, include electrically conductive materials that are vacuum-compatible at up to 400° C. (750° F.), such as alloys of steel, cast iron, aluminum, or titanium. This coating system is intended to augment bare metal designs, as well as overcome the limitations of existing non-stick cooking solutions.

Low temperature (<450° C.) nitriding and carburizing treatments, or nitrocarburizing which is also known as S-Phase formation, is a preferable pre-treatment that can be applied to any grade or class of stainless steel, such as austenitic 304, ferritic 430, martensitic 440, precipitation hardened 17-4, and duplex 2507. S-Phase formation provides a substantial increase in surface hardness of a stainless steel to about 800-1200 HV (Vickers Hardness) without negatively affecting corrosion resistance. This alleviates the sharp change in hardness between the untreated substrate and the DLC coating, greatly improving adhesion strength and durability. The S-Phase process achieves a case depth of about 5-50 micrometers deep, and can be performed in the same furnace batch prior to the DLC coating. This significantly improves the efficiency relative to separate processes, since certain unavoidable process time is shared, such as vacuum-down, heating, and cooling. It should be noted that purposes of this disclosure, such a pre-treatment (prior to the application of DLC coating) is termed intermediate layer. The purpose of the intermediate layer is to create a surface with adequate hardness prior to the formation of DLC layers. The intermediate layer is chosen from the non-limiting set of nitriding, carburizing and nitrocarburizing treatments based on the metallic component on which the coating is placed and the hardness value required. Those skilled in the art will recognize the tradeoff between hardness and toughness and will choose an intermediate layer coating suitable for the metallic material being considered.

The nitrocarburizing is accomplished through ion plasma, salt, or gas process well known in the industry. After nitrocarburizing, the DLC coating of this disclosure is applied utilizing plasma enhanced chemical vapor deposition (PECVD) vacuum process. The DLC coating of this disclosure, whether applied as a layer directly on the metallic surface or applied on top of the nitrocarburized layer, contains 20-40 weight percent (wt %) silicon, 10-30 wt % oxygen, and 1-3 wt % hydrogen, with the remainder as carbon. The plasma enhanced chemical vapor deposition (PECVD) vacuum process employed in producing the DLC coating uses a combination of gaseous or liquid precursors, such as, but not limited to, methane, acetylene, oxygen, silane, trimethylsilane, tetramethylsilane, hexamethyldisiloxane, and tetraethyl orthosilicate. The compositions of the deposited coatings are varied by the selection of the precursors and their flow ratios. The integration of silicon and oxygen into the DLC provides substantially improved hydrophobicity and non-stick properties. Advantages of the PECVD process are non-line-of-sight deposition, large batch volume, low process temperature (<450° C.), and high deposition rate (>1 μm/hr). Surface activation, prior to DLC coating is achieved by plasma sputtering with inert gas, such as argon. This represents a significant advantage over some other coating technologies that must use acids or other harsh chemicals to pre-treat metals to achieve adequate bonding of the coating.

The coating of this disclosure may be deposited on the nitrocarburized layer as a monolithic layer of a given thickness. It can also be deposited as more than one layer, commonly known as a multilayer. A multilayer may contain DLC layers of varying composition and thickness initiated via slight process variations or interruptions in growth mechanics, such as changes in precursor flows, plasma voltage, or vacuum pressure.

Those skilled in the art are familiar with the beneficial effects of multilayers on stress reduction, crack inhibition, and corrosion resistance. The total thickness of the DLC layers DLC coating thickness is about 2-20 microns, with a hardness of about 500-2500 HV. For reference, the hardness of 304 stainless steel is about 100-150 HV, and the hardness of PFTE is about 10-50 HV. Like PTFE, the DLC coating of this disclosure has a very low dry coefficient of friction (COF) of <0.1 in contact with most materials. Low COF combined with high hardness provides the DLC coating with excellent durability against wear, abrasion, and scratching.

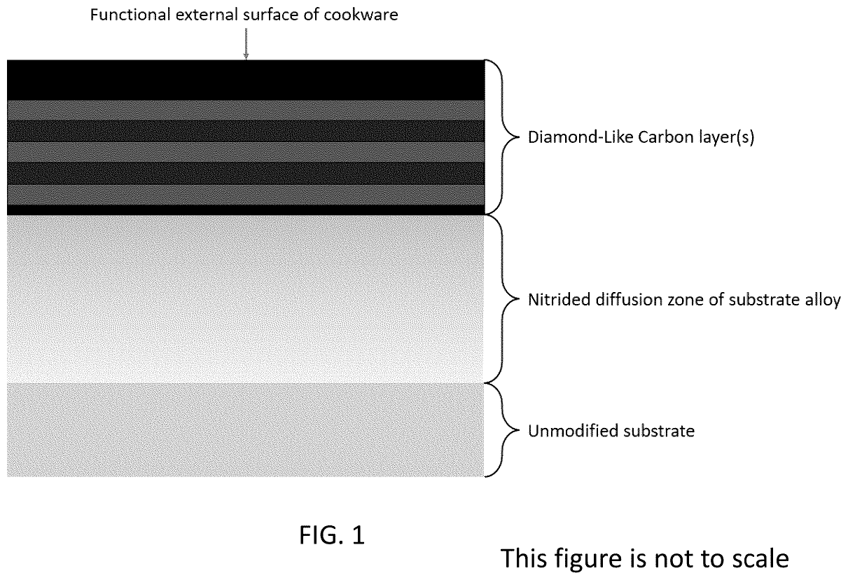

FIG. 1 shows a schematic representation of the cross section of an article comprising the coatings of this disclosure. It should be noted that that this schematic is not to scale. Referring to FIG. 1, the bottom section represents the cross-section of substrate alloy (also called substrate core). That section is not modified by any of the treatment of this disclosure. Next segment in the cross-section schematic represents the nitrocarburization layer (also called nitride diffusion zone of the substrate). The next layers are the multilayers of the DLC coating as described above. Further, the shades of DLC layers have no particular meaning; it is just to indicate they are different layers.

Some measured properties of parts made with the coatings of this disclosure are now presented.

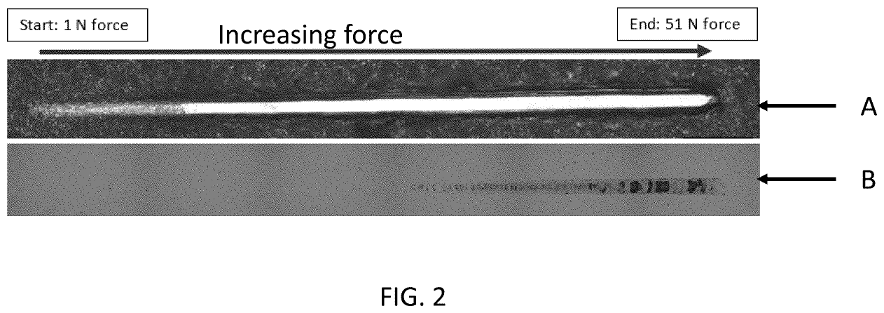

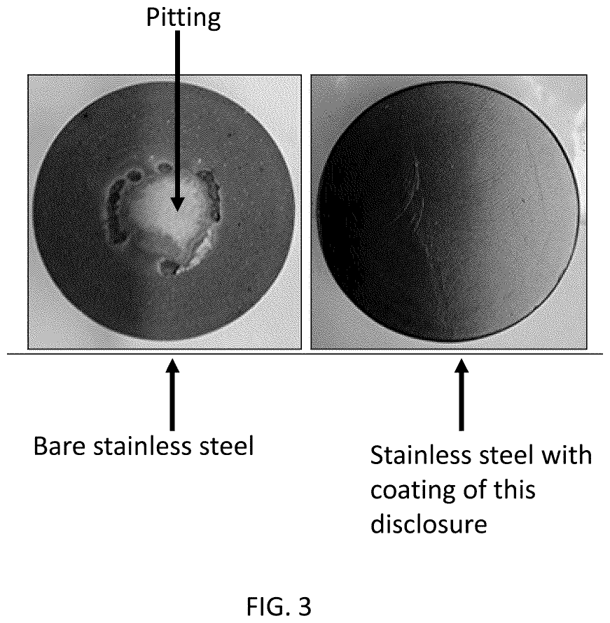

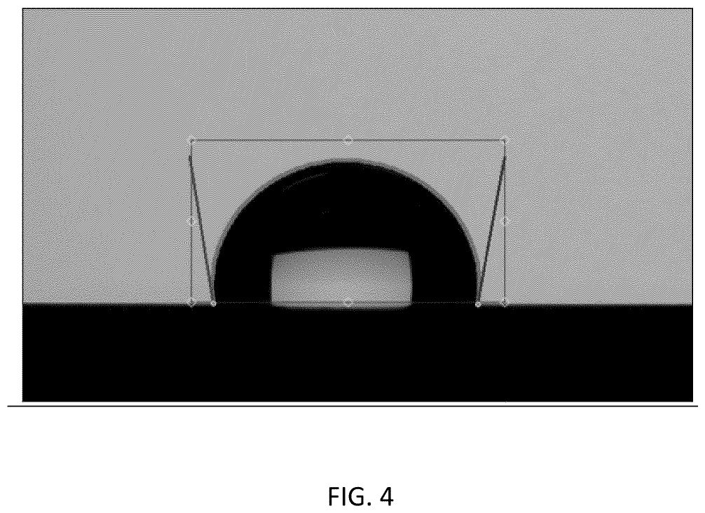

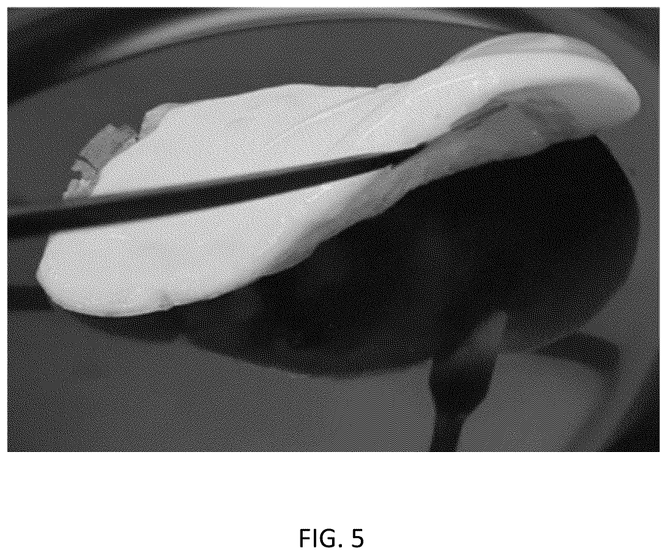

Example 1: A substrate of 304 stainless steel is pre-treated via low temperature S-Phase carburizing, with a case depth of 25 micrometers and a surface hardness of 900 HV. The surface is then coated with a monolayer of DLC about 4 micrometers in thickness, with a composition of about 42 wt % carbon, 32 wt % silicon, 25 wt % oxygen, and 1 wt % hydrogen. The DLC coating has a hardness of 1300 HV and a water contact angle of about 99 degrees. The S-Phase and DLC are performed in a sequential process at 420-440° C. This example is depicted in FIGS. 4 and 5. Example 2: A substrate of 17-4 precipitation hardened stainless steel is pre-treated via low temperature S-Phase nitrocarburizing, with a case depth of 15 micrometers and a surface hardness of 1000 HV. The surface is then coated with a multilayered DLC coating of about 15 micrometers in thickness. In this example. the multilayer contains 30 DLC layers about 0.5 micrometers in thickness each. The layers have compositions alternating between composition 1, namely 56 wt % carbon, 26 wt % silicon, 15 wt % oxygen, and 3 wt % hydrogen, and composition 2, namely 34 wt % carbon, 38 wt % silicon, 27 wt % oxygen, and 1 wt % hydrogen. The typical variation of the content of an element in these compositions is approximately +/−1%. The DLC coating has a hardness of 1600 HV and a water contact angle of about 95 degrees. The S-Phase layer and DLC layers are achieved in a duplex process at 380-400° C. This example is depicted in FIGS. 2 and 3. FIG. 2 shows ASTM C1624 scratch adhesion testing using a Rockwell C diamond-tipped indenter and a progressive load of 1-51 N across 5 mm of length. ASTM C1624 is a quantitative method of comparing scratch resistance and coating adhesion strength. In this test method, a Rockwell C diamond-tipped indenter is scraped against a coating with steadily increasing force. The scratch path is then analyzed for coating failure modes, such as cracking, chipping, or substrate exposure. FIG. 2 shows a comparison between PTFE coating (A in FIG. 2) and the DLC coating of this disclosure (B in FIG. 2) regarding their performance in the above-mentioned scratch test. The PTFE is scratched immediately, and completely removed after 5-10 N of force. After that, all that is visible is the bright appearance of the bare stainless-steel substrate as the scratch grows progressively wider and deeper. In contrast, the DLC coating of this disclosure on sample A shows no damage of any kind until about 30 N of force, after which some minor cracking is visible. At no point in the scratch did the DLC coating delaminate and expose the substrate.

Unlike most commercial non-stick coatings, the DLC coating described here is relatively thin. This minimizes detrimental thermal gradients and internal stresses during use and improves resistance to thermal shock. Another advantage is the ability to maintain the pre-existing surface finish of the cookware. Any polish or surface texture imparted into the tool, whether functional or cosmetic, will be preserved after application of the developed coating, including features such as stamped text or laser-etched logos. This allows implementation on existent components and materials with little-to-no considerations necessary for tolerances or design changes.

Cookware components can be exposed to a variety of corrosive agents present in cleaners, as well as some food products themselves. The DLC coating is chemically inert and provides extreme protection to the substrate, far exceeding the corrosion resistance of common stainless steels used in the cookware industry. Harsh chemicals such as acids (e.g. hydrochloric, sulfuric, nitric, citric, and acetic acids), bases (e.g. as sodium hydroxide, potassium hydroxide, ammonium hydroxide, and sodium carbonate), and oxidizers (e.g. sodium hypochlorite and hydrogen peroxide) have no effect on the surface coated with the DLC coating of this disclosure.

Atmospheric corrosion resistance is another important factor for the longevity of cookware equipment, particularly in humid or coastal environments. In ASTM B117 (Salt Spray) conditions, 4140 low alloy steel will rust in less than 12 hrs. In ASTM G85-Annex 4 (Acidic Salt Spray with SO2) conditions, most stainless steels will rust in less than 24 hrs. In contrast, the DLC coating of this disclosure encapsulates and protect the substrates entirely, passing over 1000 hrs. in both test conditions with zero corrosion. Since the DLC coating of this disclosure is a strong electrical insulator, galvanic corrosion is also prevented in the case of mixed-metal components or systems.

Crevice corrosion is another important consideration for cookware, since tools or surfaces are frequently left in contact with water or other liquids for extended periods as part of the cooking, storage, and cleaning processes. In particular, holes, edges, and concave surfaces can be subject to aggressive localized corrosion. In ASTM G48 (Crevice Corrosion by Ferric Chloride), most stainless steels will become heavily pitted within 24 hrs. of submersion. The DLC coating of this disclosure provides total protection, with zero pitting or corrosion after 48 hrs, as shown in FIG. 3.

In this disclosure, when we refer to DLC layers they should be understood to be either directly on the metallic surface of interest or on top of and in contact with an intermediate layer which is on top of and in contact with the metallic surface of interest. The DLC coating of this disclosure is robust and unaffected by heat exposure up to 400° C., which is well above the limits of PTFE and sol-gel ceramic coatings. Few bulk materials or coatings are immune to such an array of chemicals and corrosive conditions. Those that are suffer from other shortcomings relevant to this application, such as poor durability, high cost, or poor non-stick properties. The DLC coating of this disclosure affords the use of a multitude of desired substrate materials by modifying and protecting the surface properties of the cookware.

A common way to classify non-stick behavior is through calculation of the surface free energy. This quantifies the bonding nature of the surface and allows for predictions of how that surface will interact with other solids and liquids. The surface energy is usually split into two components: polar and dispersive. A high polar fraction indicates a surface with polar bonding, and a low polar fraction indicates a surface with non-polar bonding. The dispersive fraction represents fundamental intermolecular forces, which are much weaker than chemical bonds. Therefore, it is the polar fraction which primarily determines the presence and strength of adhesive interactions, such as tapes, paints, and foods, with different materials and coatings.

Many food products are substantially based on polar molecules, including water, carbohydrates (sugars, starch, cellulose, etc.) and salts. Non-polar, hydrophobic components include fats and oils. Proteins can be polar, non-polar, or both, depending on their initial structure and their changing state during the cooking process. It is common practice to use non-polar fats and oils to lubricate polar cooking surfaces (i.e. metal or ceramic) and prevent sticking. Therefore, a non-stick coating for cooking should be as non-polar and hydrophobic as possible.

Generally, a low surface energy <40 mN/m indicates hydrophobic and non-stick behavior. Some well-known non-stick materials display exceptionally low surface energy in the range of 20-30 mN/m, such as PTFE (˜20 mN/m), silicone rubber (˜24 mN/m), and polypropylene (˜30 mN/m). For reference, the surface energy of most metals, glasses, and ceramics is in the range of 200-1000 mN/m.

ISO 19403-2 (Surface Free Energy by Contact Angle measurement)) describes multiple models and methods for determining surface energy via the use of a goniometer and liquid drop projection. By measuring the contact angle with several well-characterized liquids, both the polar and dispersive components of surface energy can be calculated using the recommended Owens-Wendt-Rabel-Kaelble (OWRK) method. FIG. 4 shows an example water droplet contact angle test performed on the DLC coating of this disclosure, giving an average angle of 99°, indicating strong hydrophobicity. The results of testing with three recommended liquids are shown in Table 1. Following the OWRK method with these contact angles yields a calculated surface energy of 28.7mN/m for this example of the developed DLC. The calculated polar fraction is 0.8 mN/m, and the calculated dispersive fraction is 27.8 mN/m. With a polar fraction of near-zero, the developed DLC coating is practically a non-polar surface and may also be characterized by the Zisman method for surface energy. The Zisman method does not consider polar interactions, and is commonly used for classifying non-polar materials with low surface energy, such as some polymers. Using the same contact angle measurements from Table 1, the Zisman method yields a surface energy of 25.8 mN/m for the DLC coating of this disclosure.

TABLE 1
Contact angle results for the DLC coating of this
disclosure with various liquids, per ISO 19403-2.

| | Liquid | Liquid | Liquid | Contact Angle |
|---|---|---|---|---|
| | Surface | Polar | Dispersive | with the |
| | Tension | Fraction | Fraction | Developed DLC |
| Liquid | (mN/m) | (mN/m) | (mN/m) | Coating |
| Water | 72.8 | 51.0 | 21.8 | 98.7° ± 0.4 |
| Diiodomethane | 50.8 | 0.0 | 50.8 | 62.9° ± 0.6 |
| Benzyl Alcohol | 38.9 | 9.9 | 29.0 | 49.6° ± 0.7 |

The results of both models clearly show that the developed DLC coating possesses very low surface energy and excellent hydrophobic properties. The water contact angle of about 99° is close to reported values for PTFE of 105-110°. These measurements suggest a high degree of non-stick performance, which has been verified through cooking trials.

One method of testing non-stick cooking surfaces involves pan frying a chicken egg at about 180° C. (360° F.) without oil. Egg white is about 90% water and 10% protein, with practically no fat content. As the egg cooks, the proteins interconnect, trapping the water content and leading to formation of solids. Without pre-applied oil or fat, egg white will strongly bond to standard cooking surfaces, such as stainless steel. A high-performance non-stick material or coating will prevent this bonding and allow the egg to be freely manipulated without sticking. FIG. 5 shows an image of this “oil-free egg test” performed on a surface coated with the developed DLC. The egg is able to be lifted and moved around with no sticking or residues left behind, demonstrating excellent non-stick performance.

Another cooking test method involves melting table sugar at about 200° C. (390° F.) and allowing it to over-caramelize. The resulting residue of partially burnt sugar can be incredibly difficult to remove from a standard cooking surface. A similar test method exists where liquid milk is boiled down and burnt on to a cooking surface instead. Since milk contains various natural sugars, the sticking mechanisms are similar. When these tests are conducted on cookware treated with the DLC coating of this disclosure, the burnt sugar residues are completely free and unbonded from the surface.

Yet another test method involves roasting chopped potatoes in an oven at about 230° C. (450° F.). Potatoes are about 80% water, with the remainder primarily composed of starch. Roasted potatoes are well known for their tendency to stick strongly to metal baking sheets, even when oil is pre-applied to the potatoes and the sheet. However, when this test is performed on a sheet coated with the DLC coating of this disclosure, and with no pre-applied oil, the potatoes remain completely unstuck. In general, any food that is rich in protein or carbohydrates, with relatively low-fat content, is prone to sticking to conventional cooking surfaces. Other examples of these types of foods that have been tested on the DLC coating of this disclosure, without pre-applied oil, include pancakes, lean meats, fish, rice, and pasta. In all cases, the DLC coating of this disclosure provides excellent non-stick release properties. Thus, this coating not only provides an extremely durable, easy to clean surface, it also affords a chef the option of using significantly less oil or fat in their recipes for health reasons.

It should be recognized that slight modifications to the composition or multilayer structuring of the DLC coating can lead to further improvements in performance, such as increased hydrophobicity and/or decreased surface energy. Improvements to mechanical properties are also possible, such as increased hardness or adhesion strength, without compromising the non-stick properties.

It should be recognized that polyfluorinated compounds (including PTFE) are leading to deleterious effects on human health and many countries are seriously considering a ban on these materials, which makes the present disclosure a very essential component of non-stick surface technology.

While the forgoing discussion and demonstrated coating technology of this disclosure has referenced a cooking surface such as a frying pan, the applications of the compositions and methods of this disclosure are much wider. For instance, anything related to cooking, baking, roasting, or mixing are potential applications of this technology where a non-stick surface is required or beneficial. Utensils for flipping or serving are also good candidates for this technology, as are grilling plates, trays, waffle and pancake makers, air fryer screens, etc. Cutting boards employing the coatings of this disclosure also can provide non-stick surfaces as an advantage.

It is important to note that substrates on which the coatings of this disclosure are deposited can be any electrically conducting material. Typical materials include metals and alloys, such as but not limited to stainless steel. One or more layers of DLC containing oxygen and silicon can be deposited directly on the substrate or on top of a carburization layer or nitrocarburization layer. Such carburization or nitrocarburization layers produced on the substrate prior to depositing the DLC containing silicon and oxygen are termed intermediate layers for purposes of this disclosure. Thus, it should be understood that the intermediate layer or layers are optional. Stated simply, the embodiments of the disclosure fall into several categories:
substrate+intermediate layer+one or more DLC layers containing silicon and oxygen;
substrate+one or more DLC layer containing silicon and oxygen;
Here, the term “substrate” is to be understood as metallic material of interest on the surface of which a non-stick coating is desired.
   Those skilled in the art will recognize the variations embedded in the above categories. For purposes of this disclosure all the coatings encompassed in the above two sentences will be part of the “DLC coatings of this disclosure”. For purposes of this disclosure “DLC coatings” and “DLC coatings containing silicon and oxygen” are used interchangeably.

Based on the above description, it is an objective of this disclosure to describe a coating on a metallic surface wherein the coating contains one or more layers of DLC where in each layer of DLC contains silicon and oxygen. In some embodiments of the coating of this disclosure, the one or more layers of DLC are on top of and in contact with the metallic surface. Non-limiting examples intermediate layers include but not limited to nitriding layer, carburized layer and nitrocarburized layer. While there is no strict rule as to which intermediate layer is better suited to which metallic surface, it is advantageous to have nitriding and nitrocarburized layer for martensitic and ferritic steels while austenitic steels may have increased benefit from a carburized layer. This statement is not meant to exclude any intermediate layer for a metallic surface. In some embodiments of this disclosure, each layer in the DLC coating contains silicon and oxygen has silicon in the range of 20-40 weight percent and oxygen in the range of 10-30 weight percent. In some embodiments of the coatings of this disclosure, the DLC layers containing silicon and oxygen can be 4 in number. It should be recognized that the number is not limited to 4. In some embodiments of the coatings of this disclosure, the intermediate layer can be a nitrocarburized layer with a thickness in the range of 1-100 micrometers, with a preferred range of 5-50micrometers. In some embodiments, the coating of this disclosure has a hardness in the range of 500-2500 HV. In some embodiments of the coatings of this disclosure, the coating has a contact angle with water in the range of 90-110 degrees. In some embodiments the coating of this disclosure has a surface energy in the range of 15-40 mN/m. In some embodiments of the coatings of this disclosure, the thickness of the intermediate layer plus the thickness of one or more layers of DLC containing silicon and oxygen is in the range of 0.1-40 micrometers. In some embodiments without the intermediate layer, the total thickness of the one or more DLC layers can be in the range of 0.1-40 micrometers.

It is another objective of this disclosure to describe a method of producing a non-stick coating on a surface of a metallic material. The method includes producing, as an intermediate layer, one of nitriding layer, nitrocarburization layer, and carburization layer on the surface of a metallic material by one of ion plasma nitriding, gas nitriding, and salt bath nitriding; and producing, one or more layers of DLC containing silicon and oxygen on top of and in contact with the nitrocarburized layer by a plasma enhanced chemical vapor deposition (PECVD) vacuum process. In some embodiments of the method of this disclosure, the intermediate layer may be omitted and the DLC layer is deposited directly on a substrate. In some embodiments of the method of this disclosure, each layer in the DLC coating contains silicon in the range of 20-40 weight percent and oxygen in the range of 10-30 weight percent. In some embodiments of the method of this disclosure, the number of DLC layers is 4. In some embodiments of the method of this disclosure, the thickness of the nitrocarburized layer is in the range of 1-100 micrometers, with a preferred range of 5-50 micrometers. In some embodiments of the method of this disclosure, the thickness of the nitrocarburized layer is in the range of 5-20 micrometers. In some embodiments of the method, the coating has a hardness in the range of 500-2500 HV. In some embodiments of the method, the coating has a contact angle with the water in the range of 90-110 degrees. In some embodiments of the methods of this disclosure, the thickness of the intermediate layer plus the thickness of one or more layers of DLC containing silicon and oxygen is in the range of 0.1-40 micrometers. In some embodiments of the method, there can be no intermediate layer and the total thickness of the one or more DLC layers can be in the range of 0.1-40 micrometers. In some embodiments of the method precursors for the plasma enhanced chemical vapor deposition (PECVD) vacuum process are chosen from a group consisting of methane, acetylene, oxygen, silane, trimethylsilane, tetramethylsilane, hexamethyldisiloxane, and tetraethyl orthosilicate.

It is yet another objective of this disclosure to describe an article containing a surface which includes one or more layers of DLC, each layer of DLC containing silicon and oxygen. It is yet another objective of this disclosure to describe an article containing a surface containing a nitrocarburized layer; and one or more layers of DLC, each layer of DLC containing silicon and oxygen on top of and in contact with the nitrocarburized layer. Such articles include, but are not limited to, utensils used for cooking.

While the present disclosure has been described with reference to certain embodiments, it will be apparent to those of ordinary skill in the art that other embodiments and implementations are possible that are within the scope of the present disclosure without departing from the spirit and scope of the present disclosure. Thus, the implementations should not be limited to the particular limitations described. Other implementations may be possible. It is therefore intended that the foregoing detailed description be regarded as illustrative rather than limiting. Thus, this disclosure is limited only by the following claims.

1. A coating on a metallic surface comprising one or more layers of diamond-like carbon, wherein each layer of diamond-like carbon contains silicon and oxygen.

2. The coating of claim 1, wherein the one or more layers of diamond-like carbon are on top of and in contact with an intermediate layer on top of and in contact with the metallic surface.

3. The coating of claim 2, wherein the intermediate layer is one of nitriding layer, carburized layer and nitrocarburized layer.

4. The coating of claim 2, wherein each layer of diamond-like carbon contains silicon and oxygen has silicon in the range of 20-40 weight percent and oxygen in the range of 10-30 weight percent.

5. The coating of claim 2, wherein the one or more layers is 4 layers.

6. The coating of claim 2, wherein the thickness of the nitrocarburized layer is in the range of 1-100 micrometers.

7. The coating of claim 2, wherein the coating has a hardness in the range of 500-2500 HV.

8. The coating of claim 2, wherein the coating has a contact angle with the water in the range of 90-110 degrees.

9. The coating of claim 2, wherein the coating has a surface energy of 15-40 mN/m.

10. The coating of claim 2, wherein the thickness of the intermediate layer plus the one or more layers of diamond-like carbon containing silicon and oxygen is in the range of 0.1-40 micrometers.

11. A method of producing a non-stick coating on a surface of a metallic material, the method comprising:
producing on top of and in contact with the surface of the metallic material, an intermediate layer which is one of nitriding layer, nitrocarburization layer, and carburization layer on the surface of a metallic material by one of ion plasma nitriding, gas nitriding, and salt bath nitriding methods; and
producing one or more layers of diamond-like carbon containing silicon and oxygen on top of and in contact with one of the nitriding layer, the nitrocarburization layer, and the carburization layer by a plasma enhanced chemical vapor deposition (PECVD) vacuum process.

12. The method of claim 11, wherein the each layer of diamond-like carbon containing silicon and oxygen has silicon in the range of 20-40 weight percent and oxygen in the range of 10-30 weight percent.

13. The method of claim 11, wherein the one or more layers is 4.

14. The method of claim 11, where in the thickness of the nitrocarburized layer is in the range of 1 to 100 micrometers.

15. The method of claim 11, where in the non-stick coating has a hardness in the range of 500-2500 HV.

16. The method of claim 11, wherein the non-stick coating has a contact angle with water in the range of 90-110 degrees.

17. The method of claim 11, wherein the thickness of the intermediate layer plus the thickness of one or more layers of DLC containing silicon and oxygen is in the range of 0.1-40 micrometers.

18. The method of claim 11, wherein precursors for the plasma enhanced chemical vapor deposition (PECVD) vacuum process are chosen from a group consisting of methane, acetylene, oxygen, silane, trimethylsilane, tetramethylsilane, hexamethyldisiloxane, and tetraethyl orthosilicate.

19. An article comprising a surface containing one or more layers of DLC containing silicon and oxygen.

20. An article comprising a surface containing a nitrocarburized layer; and one or more layers of DLC containing silicon and oxygen on top of and in contact with the nitrocarburized layer.
